(19) United States
(12) Patent Application Publication
(10) Pub. No.: US 2009/0115052 A1
(43) Pub. Date: May 7, 2009

(54) HYBRID SILICON/NON-SILICON ELECTRONIC DEVICE WITH HEAT SPREADER

(75) Inventors: Randolph E. Treece, Westminster, CO (US); Steven Gregory Whipple, Lakewood, CO (US); John Torvik, Boulder, CO (US)

Correspondence Address: SHERIDAN ROSS PC, 1560 BROADWAY, SUITE 1200, DENVER, CO, 80202, US

(73) Assignee: Astralux, Inc., Boulder, CO (US)

(21) Appl. No.: 12/127,659

(22) Filed: May 27, 2008

Related U.S. Application Data
(60) Provisional application No. 60/940,122, filed on May 25, 2007.

(51) Int. Cl. H01L 23/488; H01L 21/44

(52) U.S. Cl. 257/706; 438/479; 438/122; 257/E23.023; 257/E21.476

(57) ABSTRACT

A hybrid electronic device incorporating both Si and non-Si semiconductor components, utilizing SiC, diamond, or another highly thermally conductive material as an underlying heat spreader. The hybrid electronic device is comprised of some combination of components fabricated in: (1) the underlying heat spreader itself; (2) a thin Si layer attached to the heat spreader via wafer bonding; and/or (3) a discrete semiconductor electronics die soldered to the heat spreader.

### FIELD OF THE INVENTION

The invention concerns the usage of hybrid wafers consisting of a thin Si layer attached via wafer bonding to an underlying highly thermally conductive substrate, thereby constituting an advanced silicon-on-insulator wafer. Specifically, the invention concerns the fabrication of electronic devices in the Si layer, with the underlying substrate serving as a heat spreader not only for such Si devices, but also for electronics fabricated as discrete devices and then attached to the heat spreader via soldering or to the Si devices via bump bonding.

### BACKGROUND OF THE INVENTION

Heat buildup is an important concern for many modern electronics. High temperatures can lead to leakage currents and parasitic capacitances, which can in turn lead to device failures such as CMOS latch-up. Silicon-on-insulator (SOI) wafers avoid many of these problems by permitting individual circuit elements to be electronically isolated, which allows for higher operational temperatures (and not coincidentally, radiation hardness). However, the introduction of an electrically isolating material (typically SiO₂) also decreases the overall thermal conductivity of the SOI Wafer compared to conventional Si.

### SUMMARY OF THE INVENTION

Embodiments of the present invention concern an advanced form of SOI in which the underlying handle material has sufficiently high thermal conductivity to overcome any thermal resistance introduced by the intermediate isolation layer, and therefore the handle acts as a heat spreader. Furthermore, both SiC and diamond (two materials proposed for the heat spreader in accordance with at least some embodiments of the present invention) have lower dielectric constants than Si (9.7 ∈ᵣ and 5.5 ∈ᵣ respectively, versus 11.7 ∈ᵣ) and therefore using these materials as the handling substrate of an advanced SOI wafer means that thinner layers of intermediate oxide are necessary to obtain the same protection from parasitic capacitances as provided by conventional SOI with Si as the handle material.

Certain embodiments of the present invention concern the use of the advanced SOI material as more than just a means to dissipate heat from electronics fabricated in the Si layer. At least some embodiments of the present invention concern the advanced SOI material as a technology platform for combining diverse electronic elements into a compact package and dissipating heat from all such elements. Electronics may be fabricated in the underlying heat spreader material itself, either prior to or after Si layer bonding. Additionally, high-power compound semiconductor electronic devices fabricated separately may be directly integrated with Si control electronics fabricated in the advanced SOI wafer by means of contact pads and bump bonding. Finally, following fabrication of the advanced SOI wafer, sections of the Si layer may be removed to allow discrete high power electronic devices to be directly soldered to the underlying heat spreader.

The term “heat spreader” is used to differentiate embodiments of the present invention from conventional heat sinks. The larger size of the heat-spreading material compared to the attached electronics allows for heat to dissipate laterally before being transferred into a conventional heat sink. Accordingly, a heat spreader may be attached to a heat sink. The high thermal conductivity of the heat spreader material, such as SiC (k˜3.5 W/cmK) also means that no wafer thinning is necessary to enhance thermal dissipation, as the heat sink itself (typically Cu or Al) will not exhibit higher thermal conductivity than the heat spreader. Therefore the heat spreader itself can be used as a handling material during device fabrication.

A wafer bonding technique has been developed for creating hybrid wafers consisting of a thin (˜1 μm) film of Si on bulk SiC. Successfully fabricated hybrid Si-on-SiC wafers may employ an intermediate layer of SiO₂ between the Si and SiC. The thickness of the SiO₂ layer is controllable by the wafer fabrication process, and can range from 60 nm to 400 nm, but the process should provide for infinitely variable thickness. Several different polytypes and grades of SiC have been used.

Electronic elements can be fabricated in the Si layers of the hybrid Si-on-SiC wafers. Experiments with these elements have shown the Si layers to be device grade in terms of mobility. Furthermore, high-resolution cross-sectional transmission electron microscopy has shown the Si layer to be monocrystalline in nature, and that the SiC/SiO₂ and SiO₂/Si interfaces are uniform and substantially without voids.

Testing of the electronic elements has shown the device-to-device isolation properties of the hybrid Si-on-SiC wafers to be equal to that of conventional SOI wafers. Self-heating electronic elements fabricated in the Si layer exhibited up to 50% lower device temperatures at given power levels than identical elements fabricated in conventional SOI and bulk Si, thus proving the merit of the underlying SiC as a heat spreader.

A high power SiC BJT device can be bump-bonded to electrical contacts fabricated on the Si layer of a hybrid Si-on-SiC wafer. In such an embodiment, the BJT exhibits 125% higher gain levels in this configuration than when tested as a bare die, further indicating the heat-spreading properties of the underlying SiC. In testing, this same BJT was then removed and soldered directly to a bare piece of SiC, where it exhibited 150% higher gain levels than as a bare die.

Certain embodiments of the present invention concern the utilization of the hybrid Si-on-SiC wafer not only as an advanced form of SOI, but as a platform technology which allows Si electronics fabricated in the wafer itself to be closely incorporated with discrete electronic devices attached either by bump bonding or soldering. At least some embodiments of the present invention also concern future developments of this platform technology, such as integrating electronics fabricated in the underlying SiC itself (either before or after the wafer bonding process), utilizing other highly thermally conducive materials such as diamond (having a thermal conductivity of k˜18 W/cmK to k˜20 W/cmK, depending upon the purity of the diamond) for the hybrid wafer handle, and replacing the intermediate SiO₂ layer with a more thermally conductive insulating material such as SiNₓ.

It is thus one aspect of the present invention to provide for the attachment of discrete electronic dies to electronics in the Si layer of advanced SOI wafers by means of bump bonding.

It is another aspect of the present invention to provide for the attachment of discrete electronic dies to the handle material of advanced SOI wafers by means of backside soldering.

It is still another aspect of the present invention to provide for the fabrication of electronics in the handle material of advanced SOI wafers prior to wafer fabrication.

It is still another aspect of the present invention to provide for the fabrication of electronics in the handle material of advanced SOI wafers after wafer fabrication.

It is still another aspect of the present invention to provide for a combination of the above-described aspects.

It is still another aspect of the present invention to incorporate discrete electronic dies with Si-layer electronics in advanced SOI wafers by means of wire bonding.

It is still another aspect of the present invention to incorporate the handle material electronics with Si-layer electronics in advanced SOI wafers by means of wire bonding.

It is still another aspect of the present invention to utilize oversized (larger in area than the constituent electronics) advanced SOI chips in conjunction with certain embodiments of the present invention to permit lateral heat spreading before dissipation into a heat sink.

It is still another aspect of the present invention to utilize any highly-thermally conductive material as the handle material for the advanced SOI wafer.

It is still another aspect of the present invention to utilize any highly thermally conductive, electrically insulating material as the intermediate layer in the advanced SOI wafer.

The summary is not intended to provide an exhaustive description of all embodiments of the present invention. Namely, additional features and advantages of embodiments of the present invention will become more readily apparent from the following description, particularly when taken together with the accompanying drawings.

### BRIEF DESCRIPTION OF THE DRAWING

FIG. 1 displays a discrete electronic device inverted and bump bonded (flip-chip soldered) to a hybrid Si-on-SiC or similarly advanced SOI substrate in accordance with at least some embodiments of the present invention;

FIG. 2 displays a discrete electronic device that has been soldered to a region of a hybrid wafer where the Si and SiO₂ layers have been removed in accordance with at least some embodiments of the present invention;

FIG. 3 displays a hybrid wafer where electronic devices have been fabricated in the underlying handle material in accordance with at least some embodiments of the present invention;

FIG. 4A depicts a first step in an exemplary process of fabricating the device of FIG. 1;

FIG. 4B depicts a second step in an exemplary process of fabricating the device of FIG. 1;

FIG. 4C depicts a third step in an exemplary process of fabricating the device of FIG. 1;

FIG. 5A depicts a first step in an exemplary process of fabricating the device of FIG. 2;

FIG. 5B depicts a second step in an exemplary process of fabricating the device of FIG. 2;

FIG. 5C depicts a third step in an exemplary process of fabricating the device of FIG. 2;

FIG. 5D depicts a fourth step in an exemplary process of fabricating the device of FIG. 2;

FIG. 6A depicts a first step in an exemplary process of fabricating the device of FIG. 3;

FIG. 6B depicts a second step in an exemplary process of fabricating the device of FIG. 3;

FIG. 6C depicts a third step in an exemplary process of fabricating the device of FIG. 3;

FIG. 7A depicts output RF power as a function of input RF power from results obtained from a first experiment conducted with a device fabricated in accordance with at least some embodiments of the present invention;

FIG. 7B depicts a log-log plot of the data depicted in FIG. 7A;

FIG. 8 depicts I-V results of a test conducted with a Bipolar Junction Transistor (BPJ) while still part of a whole SiC wafer and the corresponding configuration of tested elements;

FIG. 9 depicts I-V results of a test conducted with a bare BJT die cut and flip-chip bump-bonded to a hybrid Si-on-SiC wafer and the corresponding configuration of tested elements;

FIG. 10 depicts I-V results of a test conducted with a bare BJT die that is backside bonded to a SiC substrate and the corresponding configuration of tested elements; and

FIG. 11 depicts I-V results of a test conducted for a BJT die unbonded and tested directly on stage and the corresponding configuration of tested elements.

### DETAILED DESCRIPTION OF THE INVENTION

Methods for incorporating electronics fabricated in the Si layer of an advanced SOI wafer with high power electronic devices of a different material, such as SiC, GaAs or any other semiconductor element or compound are provided. At least some embodiments of the present invention allow for the electronics to be combined in close proximity, thereby reducing overall device footprint and potentially decreasing signal noise between the Si electronics and the high power devices. The underlying highly thermally conductive handle material of the advanced SOI wafer serves as a heat spreader for both the Si electronics and the incorporated high-power electronics. By providing a thermally conductive handle layer that effectively spreads the heat away from the Si electronics and incorporated high-power electronics, embodiments of the present invention allow Si-based electronics to operate at a greater efficiency, for a longer time, all while decreasing the risk of having the electronics fail.

The incorporation of the high-power electronics with the Si electronics can be accomplished in a number of different ways in accordance with at least some embodiments of the present invention. Three possible ways of incorporating the high-power electronics with the Si electronics will be discussed in further detail herein without intending to limit the scope of the invention.

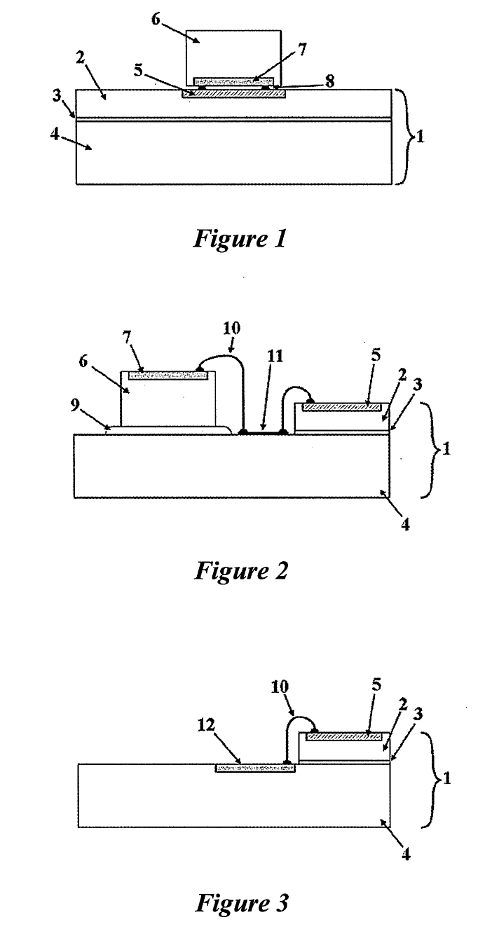

Referring initially to FIG. 1, a hybrid wafer 1 is provided that includes an Si layer 2, an intermediate insulation layer (SiO₂ or SiNₓ) 3, and a handle material (SiC, diamond or other high-thermal conductivity substance) 4. The handle material 4 will be referred to as the SiC layer 4 for ease of description only. Such references to the SiC layer 4 should not be construed to limit the handle material 4 to a single type of substance. Accordingly, the hybrid wafer 1 may be referred to as a Si-on-SiC hybrid even though the hybrid wafer 1 actually has a Si-on-high-thermal conductivity substrate composition.

Electronics 7 fabricated in the discrete device are shown on the bottom side of a discrete semiconductor electronics die 6. These may be directly incorporated by bump bonding (flip-chip) or solder connections 8 with electronics 5 fabricated in the Si layer of the hybrid wafer.

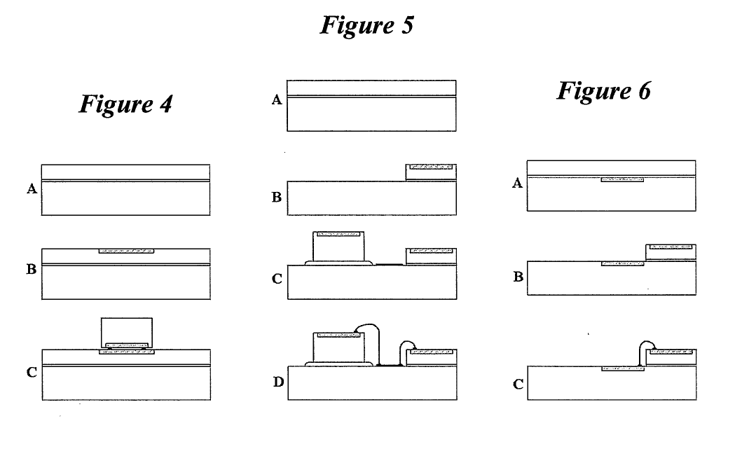

Referring now to FIGS. 4A-C, a method of fabrication the hybrid wafer 1 shown in FIG. 1 will be described in accordance with at least some embodiments of the present invention. Initially, the hybrid wafer 1 is fabricated by utilizing known layer deposition technology. More specifically, the insulation layer 3 is deposited on the SiC layer 4. Thereafter, the Si layer 2 is deposited on the insulation layer 3. Then, electronics 5 are fabricated in the Si layer 2 using standard Si processing techniques such as diffusion, RIE etching, photolithography, contact formation, etc.

The semiconductor electronics 7 can be separately fabricated and cut into a die, the electrical contacts of which are then flip-chip bump-bonded 8 to contacts on the Si electronics 5. This allows the two individual electronic circuits 5 and 7 to be directly incorporated with each other without wire bonds. However, if the high-power device 6, 7 possesses backside contacts, these may be connected to contacts in the Si electronics by wire bonding. As an example, with this method a high-power SiC transistor die could be connected to Si gate control electronics to create a power converter.

With reference now to FIG. 2, a second possible configuration of hybrid wafer elements will be described in accordance with at least some embodiments of the present invention. The hybrid wafer 1 depicted in FIG. 2 is similar to the wafer 1 depicted in FIG. 1, except that the Si layer 2 and intermediate insulation layer 3 comprise a surface area that is less than the surface area of the SiC layer 4. Thus, the discrete semiconductor electronics die 6 and its associated electronics 7 may be situated next to the Si layer 2, rather than on top of it. In such a configuration, the orientation of the discrete semiconductor electronics die 6 may be reversed whereby the semiconductor electronics 7 face away from the SiC layer 4. A solder layer 9 such as AuSn, AuGe, and the like may then be provided to connect the backside of the discrete semiconductor electronics die 6 to the SiC layer 4. Since the semiconductor electronics 7 and the Si layer electronics 5 are not facing one another, a surface metal connection area 11 may also be provided on the SiC layer 4. Top-side wire bonds 10 may then connect the individual electronics 5, 7 to the surface metal connection area 11 to provide electrical connectivity between the electronics.

As can be seen in FIGS. 5A-D, during fabrication of the electronics 5, 7 in Si of the hybrid wafer, a region of the wafer 1 may be etched to remove the Si 2 and insulator layers 3, thereby revealing patches of bare SiC (or whatever the underlying handle material may be). This exposed area is then covered with Al/Au or another metal and/or series of metals by standard metal deposition processes. The resulting metalized patch of handle material 9 then serves as a region where the backside of a high power electronics die 6 may be soldered to the hybrid wafer 1 via solder preforms and a die bonder, or by other similar mechanisms. Contacts on the high-power die 6, 7 are then connected to contacts in the Si electronics 5 of Si of the hybrid wafer by wire bonds 10 and conductive metal lines 11 fabricated on the SiC layer 4. If the high-power die possesses 6 a backside contact, an extension of the metalized region may be connected to the Si electronics by additional wire bonds. As an example, a high-frequency X-band GaAs amplifier die could be connected with Si signal processing circuits to form a planar array radar T/R module.

FIG. 3 depicts a third possible configuration of hybrid wafer elements in accordance with at least some embodiments of the present invention. The Si layer 2 and intermediate insulation layer 3 depicted in FIG. 3 are similar to the corresponding layers depicted in FIG. 2. FIG. 3, however, shows that electronics 12 (e.g., a single device or electronic circuitry) can be fabricated in the SiC layer 4. Such fabrication of the electronics 12 can be conducted either prior to or after wafer bonding of the Si layer 2. The electronics 12 may be connected to the Si layer electronics 5 by top-side wire bonds 10.

FIGS. 6A-C depict an exemplary fabrication process in accordance with at least some embodiments of the present invention. As noted above, prior to hybrid wafer 1 fabrication, electronics 12 can be fabricated in the handle material 4. Following the addition of the Si 2 and insulator 3 layers by wafer bonding techniques, electronics 5 are fabricated in the Si layer 2 while simultaneously the area encompassing the underlying handle material electronics 12 is etched to remove the Si 2 and insulator 3 layers, thereby exposing said handle material electronics 12. Wire bonds 10 are then used to connect the high-power handle material electronics 12 to the Si layer electronics 5. Alternatively, other processes could be employed to fabricate the handle electronics 12 after the creation of the hybrid wafer 1, or even after the fabrication of the Si electronics 5. As an example, high-power radio-frequency transmission electronics could be fabricated in a SiC wafer 4, which would then become the handle material of a hybrid wafer 1, whereon control electronics 5 for the SiC device would be fabricated in the Si layer 4.

It should be appreciated that the figures are not necessarily drawn to scale. For example, the handle material 4 of a hybrid wafer 1 may be about 300 μm in thickness, while the Si layer 2 may be about 1 μm.

Certain embodiments of the present invention also cover any combination of the above three methods, such as a device containing both backside-soldered and bump-bonded high-power dies. Furthermore, at least some embodiments of the present invention cover not only high-power applications, but any application where the above described methods improve device performance.

### EXAMPLE 1

### High Frequency Applications

An X-band GaAs amplifier was backside-soldered to a SiC substrate to test the concept of heat spreading in relation to certain embodiments of the present invention. The M/A-COM MAAPGM0079 GaAs die used for this experiment is a three stage GaAs power amplifier utilizing field-effect transistors (FETs) fabricated with silicon-like manufacturing processes. It is rated at 20 watts of saturated output power over the 8-10 GHz band and has a power added efficiency rating of 30% (meaning that 70% of the combined RF and DC input power goes directly into waste heat which must be removed from the device to avoid performance degradation or failure).

Semi-insulating B-grade 6H on-axis SiC substrates measuring 360 μm thick were diced into squares measuring 12.76×12.76 mm for use in these experiments. A SiC square was coated with 1 μm of Au to prevent signal loss into the SiC. The GaAs amplifier was soldered directly upon the Au-coated SiC with an 80/20 Au/Sn solder perform.

The SiC substrate and the attached die were then epoxied directly upon a copper housing. Epoxy was employed rather than solder to avoid problems associated with the differences in coefficient of thermal expansion between SiC and Cu. The epoxy used was H20E-HC, which has a relatively high thermal conductivity (for such materials) of 9 W/mK. The thickness of the epoxy layer after adhesion of the SiC to the Cu was approximately 50 μm. The copper housing was attached directly to an aluminum heat sink, which was cooled via the small fan. No thermal grease or solder was employed between the Cu and Al.

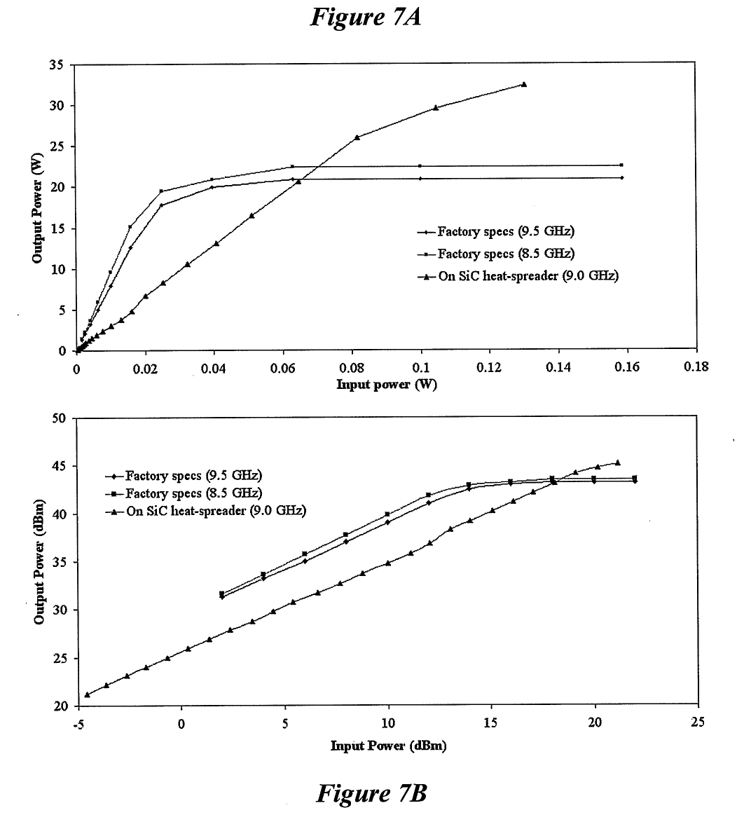

For the testing, the gate voltage was set to the factory-recommended −2.2 V while the drain voltage was ramped to the recommended 10 V. The gate voltage was then adjusted to set the quiescent drain current (no RF input) to optimal levels. RF input was then applied at 9 GHz at various power levels to observe the resulting power output. No signal tuning was attempted. FIG. 7 shows not only the power levels as tested, but also the manufacturer's specified performance levels for the MAAPGM0079 die (FIG. 7A shows the data in watts, while FIG. 7B shows the same data in dBm). It is important to note that the factory specs are representative of the make of the die rather than the actual performance levels tested for the specific die used in this project. Nevertheless, M/A-COM claims their GaAs device fabrication process is extremely consistent (indeed, no spread is given in the factory device performance specifications), and in any case, it seems unlikely that M/A-COM would publish device specs with lower performance than is typical.

It is apparent from FIGS. 7A-B that the SiC-mounted die is exhibiting less output at low power levels than given by the factory specs, but greater output at high power. This can be understood by noting that the gain (represented by curve slope) of the mounted die is lower than that of the factory specs, but the saturation power (maximum level attained) is higher. At 0.13 W of input power, the output of the SiC-mounted device is approximately 32 W, while the factory claims only approximately 21 W at this level. This increase of over 50% indicates a lower device temperature, and therefore improved thermal management due to the presence of the SiC heat spreader.

While saturation power in FETs is highly dependent upon device temperature, FET gain levels are far less temperature sensitive. This is apparent in both our test of the SiC-bonded amplifier and the factory specs by the relatively unchanging slope in the curves before saturation power is achieved; if temperature was impacting gain in a significant way, these slopes would curve downward gradually over their entire range, rather than the abrupt change that is observed when saturation power is reached. Therefore the lower gain levels seen in the SiC-mounted substrate are likely due to a testing parameter. Because the device is three-stage, this difference of approximately 5 dBm between the SiC-mounted and unmounted (factory) performance translates into a difference of approximately 1.71 dBm per stage (the lower gain at each stage is compounded by the next one, i.e.: 1.713=5). This amount is typical for the variance that a single-stage device might exhibit depending on the level of tuning that is performed. Given that no device tuning was performed in our tests, and that it is likely that M/A-COM tuned their devices as well as possible for the die's published performance levels, it is not unexpected that the gain levels revealed by our tests would not equal the factory claims.

### EXAMPLE 2

### High Power Applications

A SiC Bipolar Junction Transistor (BJT) die was backside-soldered to a SiC substrate to test the concept of heat spreading in relation to certain embodiments of the present invention. The BJT die used for these tests was a non-commercially available experimental device supplied by Mirosemi, Inc. The die measured 1×3 mm and approximately 300 μm thick, and consisted of six individual BJT structures.

Semi-insulating D-grade 6H on-axis SiC substrates measuring 360 μm thick were cleaved into pieces measuring approximately 5×5 mm for use in these experiments. A SiC piece was coated with 100 nm of Au to allow for solder adhesion. The SiC die was soldered directly upon the Au-coated SiC with an 80/20 Au/Sn solder perform.

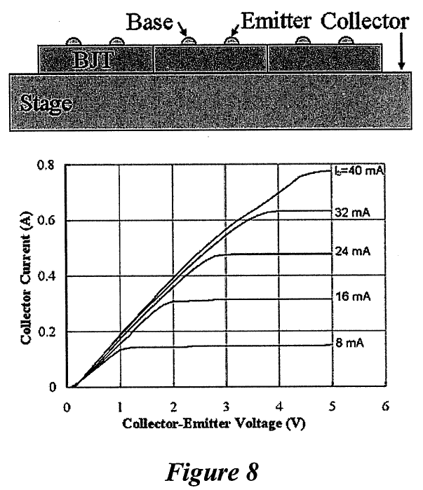

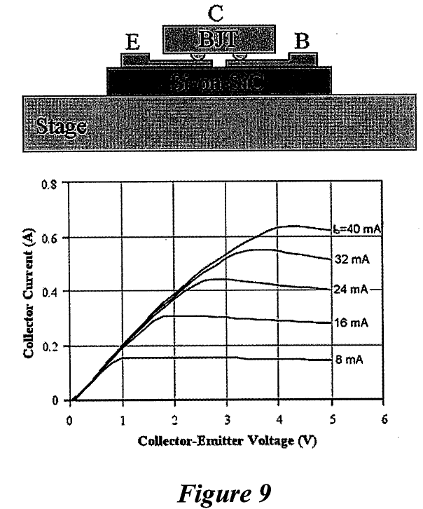

Electronic testing of the active die was performed with the bonded SiC piece sitting directly on the vacuum chuck of the same parameter analyzer previously used to test the die on-wafer and as flip-chip bump-bonded to a hybrid Si-on-SiC wafer (both tests had been performed for an earlier research project). The vacuum chuck consists of a large steel plate and serves as a heat sink for the device being tested. The original results of the on-wafer BJT and as a cut die bump-bonded to hybrid Si-on-SiC can be seen in FIGS. 8 and 9, respectively.

In general, as device temperature increases, device performance is impaired and transistor gain levels drop. Therefore, the gain levels exhibited by a transistor can be used to examine how well certain device configurations and mountings dissipate heat. The I-V curves seen in FIGS. 8 and 9 are created by quickly and repeatedly sweeping the input current and voltage levels which causes the tested device to self-heat. When the amount of power being applied is balanced by the heat dissipating through the device and into the stage (and into the air, as well as into thermal radiation), the device reaches thermal equilibrium. Actual device temperatures were not measured, but clearly the device dissipates heat better when still part of a full wafer than when cut into a single die and flip-chip bump-bonded to a hybrid Si-on-SiC wafer: the gain levels are approximately 26% higher with the die still in the uncut wafer. The inferior heat dissipation in the case of the bump-bonded die may be due to the need for heat to pass through the 12 bump bonds and underlying layers of the hybrid wafer before being dissipated by the SiC.

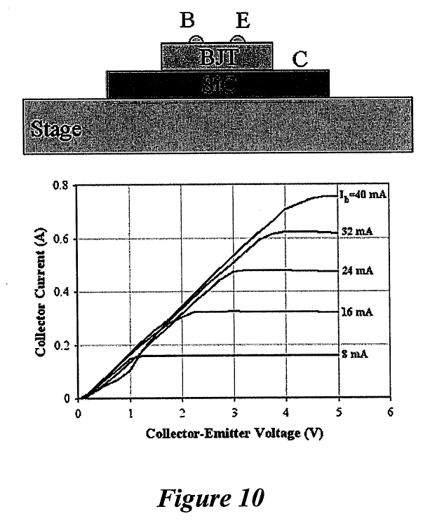

FIG. 10 shows the results of the die as backside-bonded to a SiC piece. The gain levels achieved by backside bonding are approximately 23% higher than in the case of flip-chip bump-bonding, and nearly equal to the on-wafer results. This indicates similar overall heat dissipation between the on-wafer and backside-bonded cases. However, the two arrangements are significantly different in their geometries, and therefore it is likely that the heat dissipation occurs in significantly different ways. In the case of the on-wafer results, the die has not yet been cut from the wafer and heat is free to spread laterally from the device before dissipating into the underlying vacuum stage. With the die cut and backside-bonded to a piece of SiC, all heat generated (minus the effects of radiation and air) must first be dissipated straight down through the small 1×3 mm base of the die, after which it is free to spread in underlying bulk SiC piece and then out to the vacuum stage.

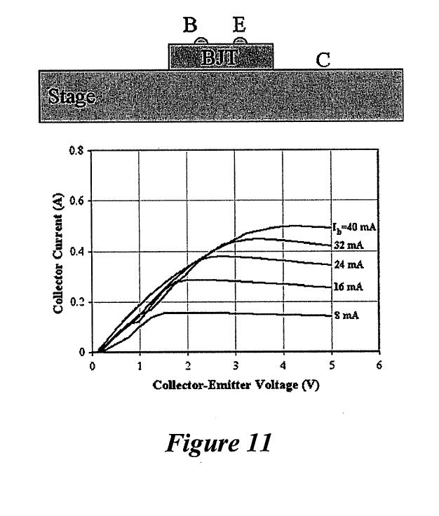

In an effort to determine the overall effect that lateral heat spreading has on the performance of an on-wafer device, the backside-bonded die was removed from the bulk SiC and tested directly on the stage. The removal was achieved by heating the bonded die and SiC substrate to over 282 C to re-melt the solder; the fact that the die could not be laterally displaced on the substrate with tweezers until the melting point had been reached is further evidence of the robustness of the backside bonding technique. The I-V test results of the unbonded die can be seen in FIG. 11. A comparison between the on-wafer and cut die results clearly shows that the BJT performance is degraded by cutting the die out, indicating lateral heat spreading in the original on-wafer configuration is an important contributor to gain magnitude. Likewise, a comparison between the cut die as unbonded and as backside-bonded shows that backside bonding to SiC improves gain by approximately 52%.

The fact that even the bump-bonded results are superior to those of the unbonded die suggests that placing a very high thermal conductivity material below a power device can significantly improve performance, even with the presence of an intermediate heat ‘bottleneck’ such as the bump bonds themselves. The bump-bonding technique could still prove useful for situations where direct incorporation of a power device to Si electronics is desired without any wire-bonding. However, as FIG. 10 shows, backside bonding is a more effective technique to maximize heat dissipation and performance from a cut die.

While the above-descriptions have been discussed in relation to a particular sequence of events, it should be appreciated that changes to this sequence can occur without materially effecting the operation of the invention. Additionally, the exact sequence of events need not occur as set forth in the exemplary embodiments. The exemplary techniques illustrated herein are not limited to the specifically illustrated embodiments but can also be utilized with the other exemplary embodiments and each described feature is individually and separately claimable.

In addition to or in place of the described power converter and radar T/R module systems, methods and protocols of this invention can be implemented on electronics such as are used in a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device such as PLD, PLA, FPGA, PAL, a communications device, such as a phone, any comparable means, or the like.

It is therefore apparent that there has been provided, in accordance with the present invention, systems and methods for creating and utilizing advanced hybrid-wafer electronics. While this invention has been described in conjunction with a number of embodiments, it is evident that many alternatives, modifications and variations would be or are apparent to those of ordinary skill in the applicable arts. Accordingly, it is intended to embrace all such alternatives, modifications, equivalents and variations that are within the spirit and scope of this invention.

What is claimed is:

1. A Silicon-on-insulator wafer, comprising:
a Silicon layer;
a intermediate insulation layer; and
a handle layer, wherein the intermediate insulation layer resides between the Silicon layer and the handle layer and wherein the handle layer dissipates heat from the Silicon and intermediate insulation layers.

2. The wafer of claim 1, further comprising electronics that are incorporated in the Silicon layer that generate the heat which is dissipated by the handle layer.

3. The wafer of claim 2, wherein the electronics incorporated in the Silicon layer are in electrical communication with separate electronics and wherein the electronics incorporated in the Silicon layer are exposed on a surface of the Silicon layer that opposes a surface of the Silicon layer that interfaces with the intermediate insulation layer.

4. The wafer of claim 3, wherein the separate electronics are in electrical communication with the electronics incorporated in the Silicon layer via bump bonding.

5. The wafer of claim 3, wherein the separate electronics are in electrical communication with the electronics incorporated in the Silicon layer via backside soldering.

6. The wafer of claim 3, wherein the separate electronics are incorporated in a discrete semiconductor electronics die.

7. The wafer of claim 6, further comprising a surface metal connection area on the handle layer wherein the separate electronics and electronics incorporated in the Silicon layer are in electrical communication with one another via the surface metal connection area.

8. The wafer of claim 3, wherein the separate electronics are incorporated in the handle layer.

9. The wafer of claim 1, wherein the handle layer comprises a high-thermal conductivity substance.

10. The wafer of claim 9, wherein the high-thermal conductivity substance comprises at least one of SiC and diamond.

11. The wafer of claim 1, wherein the intermediate insulation layer comprises at least one of SiO₂ and SiNₓ.

12. The wafer of claim 1, wherein the Silicon layer and intermediate insulation layer comprise a surface area that is less than a surface area of the handle layer.

13. The wafer of claim 1, wherein handle layer comprises a thickness of about 300 μm and the Silicon layer comprises a thickness of about 1 μm.

14. A method of manufacturing a Silicon-on-insulator wafer, comprising:
providing a handle layer;
depositing an intermediate insulation layer on the handle layer;
depositing a Silicon layer on the intermediate insulation layer; and
wherein the handle layer comprises a thermal conductivity sufficient to dissipate heat from the Silicon and intermediate insulation layers.

15. The method of claim 14, further comprising:
providing first electronics in the Silicon layer;
providing second electronics; and
connecting the first electronics with the second electronics.

16. The method of claim 15, wherein the second electronics are provided on a discrete semiconductor electronics die.

17. The method of claim 16, wherein the first and second electronics are connected via bump bonding.

18. The method of claim 16, wherein the first and second electronics are connected via backside soldering.

19. The method of claim 15, wherein the second electronics are provided in the handle layer.

20. The method of claim 19, wherein the second electronics are fabricated in the handle layer prior to depositing the intermediate insulation layer on the handle layer.

21. The method of claim 15, wherein the handle layer comprises a surface area that is larger than a surface area of either the first electronics or second electronics.

22. The method of claim 15, wherein the first electronics are fabricated using at least one of diffusion, etching, photolithography, and contact formation.

23. The method of claim 14, wherein the handle layer comprises a thermal conductivity of about 3.5 W/cmK.

24. The method of claim 14, wherein the handle layer comprises at least one of SiC and diamond.

25. The method of claim 14, wherein the intermediate insulation layer comprises at least one of SiO₂ and SiNₓ.

26. The method of claim 14, wherein handle layer comprises a thickness of about 300 μm and the Silicon layer comprises a thickness of about 1 μm.

27. The method of claim 14, further comprising:
etching at least a portion of the intermediate insulation layer and the Silicon layer to expose a corresponding portion of the handle layer.

28. A Silicon-on-insulator wafer made by a process, comprising:
providing a handle layer;
depositing an intermediate insulation layer on the handle layer;
depositing a Silicon layer on the intermediate insulation layer; and
wherein the handle layer comprises a thermal conductivity sufficient to dissipate heat from the Silicon and intermediate insulation layers.

29. The wafer of claim 28, the process further comprising:
providing first electronics in the Silicon layer;
providing second electronics; and
connecting the first electronics with the second electronics.

30. The wafer of claim 29, wherein the second electronics are provided on a discrete semiconductor electronics die.

31. The wafer of claim 30, wherein the first and second electronics are connected via bump bonding.

32. The wafer of claim 30, wherein the first and second electronics are connected via backside soldering.

33. The wafer of claim 29, wherein the second electronics are provided in the handle layer.

34. The wafer of claim 33, wherein the second electronics are fabricated in the handle layer prior to depositing the intermediate insulation layer on the handle layer.

35. The wafer of claim 29, wherein the handle layer comprises a surface area that is larger than a surface area of either the first electronics or second electronics.

36. The wafer of claim 29, wherein the first electronics are fabricated using at least one of diffusion, etching, photolithography, and contact formation.

37. The wafer of claim 28, wherein the handle layer comprises a thermal conductivity of about 3.5 W/cmK.

38. The wafer of claim 28, wherein the handle layer comprises at least one of SiC and diamond.

39. The wafer of claim 28, wherein the intermediate insulation layer comprises at least one of SiO₂ and SiNₓ.

40. The wafer of claim 28, wherein handle layer comprises a thickness of about 300 μm and the Silicon layer comprises a thickness of about 1 μm.

41. The wafer of claim 28, the process further comprising:
etching at least a portion of the intermediate insulation layer and the Silicon layer to expose a corresponding portion of the handle layer.
